(19) United States
(12) Patent Application Publication
(10) Pub. No.: US 2010/0043868 A1
(43) Pub. Date: Feb. 25, 2010

(54) System and method for integrated solar power generator

(76) Inventors: David Sun, San Diego, CA (US); Chuck Wu, San Gabriel, CA (US)

Correspondence Address: Jian Chen, 1200 Pine St, Palo Alto, CA, 94301, US

(21) Appl. No.: 12/221,803

(22) Filed: Aug. 6, 2008

(51) Int. Cl. H02N 6/00; H01L 31/042

(52) U.S. Cl. 136/251; 136/244

(57) ABSTRACT

Apparatuses, methods, and systems directed to an integrated solar electric power generation system. Some embodiments of the present invention allow the integrated solar electric power system to be plugged into a wall outlet to supply electrical power via an extension cord. Other embodiments of the present invention can be used outdoors and plugged into an outdoor wall outlet. Yet other embodiments of the present invention comprise integrated solar electric power systems that may be used indoors and connected to an indoor wall outlet to supply the generated electric power.

### TECHNICAL FIELD

This invention relates to an integrated solar electric power generation system.

### BACKGROUND

Compared with most other energy sources, solar energy is cleaner and more available. There is abundant supply of solar energy from its source, the Sun. Solar light energy can be converted to electricity to power households, buildings, factories, appliances, and other places or devices where electrical power is needed. Although solar power is widely used in electronic devices such as calculators or watches, its use in residential and industrial settings is relatively limited. High cost of solar electric power systems and complexity in the installation and connection of such systems to existing electrical systems present challenges to customers of solar electric power systems.

Existing solar electric power systems for residential or industrial use carry a high entry cost. For example, the cost of a 2 kilowatt (KW) photovoltaic (PV) system is estimated at $13,000 to $20,000 by the California Energy Commission. A 2 KW system with 16% efficient PV modules requires a relatively large 160 square feet of open space for installation. In addition, such systems typically require the installation of one or more solar panels or PV modules on top of a roof of a building structure, in an open space such as the front yard or the backyard of a building, or on the balcony of an apartment building. Qualified electricians are needed to modify the electrical service panel of a house or building so that the solar generated electrical power can be used to supply household power consumption and/or to sell excess power back to the electric utility company.

The relatively high entry cost is a major barrier for many potential consumers of solar electric power systems. However, with the rapidly increasing solar panel manufacturing capacity, the cost of solar electric power system is quickly decreasing. The efficiency of solar PV modules to convert light energy into electrical power is also improving. Therefore, the size of a solar panel may decrease for a system that is capable to power a typical residential home.

However, installing solar panels on rooftops presents not only installation challenges, but also aesthetic concerns. Many local communities established rules prohibiting the installation of solar panels on rooftops or other parts of a house due to aesthetic concerns. The requirement to have qualified electricians to modify the electrical service panels also presents problems for prospective customers of solar electric power systems.

In this and other contexts, a key factor that limits the adoption of solar electric power systems is the system installation and the challenge to supply generated electrical power to the existing electrical system for power consumption. For a typical residential home or an office building, it is common to have limited open space for solar electric power system installation. To ensure wide adoption, a solar electric power system may need to be easily installed in a limited open space environment, or even indoors. The system may also need to be easily connected to the electrical system of a household or building to supply electrical power, ideally without any modification to the existing electrical service panels.

### SUMMARY

The present invention provides apparatuses, methods, and systems directed to an integrated solar electric power generation system. Some embodiments of the present invention allow the integrated solar electric power system to be plugged into a wall outlet to supply electrical power through an extension cord. Other embodiments of the present invention can be used outdoors and be plugged into an outdoor wall outlet. Yet other embodiments of the present invention comprise integrated solar electric power systems used indoors and connected to an indoor wall outlet to supply the generated electrical power.

In one embodiment of the present invention, the apparatuses and methods are directed to an integrated solar power generation system which comprises one or more solar modules and one or more inverters. The solar modules comprise one or more solar cells that convert solar light energy to DC electrical power. The inverters monitor the converted electrical power and convert the DC power to AC power. A connector that is connected to the inverters may supply the AC power to a wall outlet when the connector is connected to the wall outlet via an extension cord.

In other embodiments of the present invention, the apparatuses, methods, and systems involve integrated solar electric power systems that may be used outdoors and may be connected to an outdoor wall outlet to supply the generated electrical power without modifying the electrical service panel. In some other embodiments of the present invention, an integrated solar electric power system may be used indoors and plugged into a wall outlet to supply the generated electrical power without modifying the electrical service panel.

The following detailed description together with the accompanying drawings will provide a better understanding of the nature and advantages of various embodiments of the present invention.

### DESCRIPTION OF THE DRAWINGS

FIG. 1 is a diagram showing an example integrated solar power generation system, which system may be used with an embodiment of the present invention.

FIG. 2 is a diagram showing an example system architecture for an integrated solar power generation system, which may be used by an embodiment of the present invention.

FIG. 3 is a diagram showing a flowchart of the example process used for generating AC electric power by an integrated solar electric power generation system, which process may be used by an embodiment of the present invention.

### DESCRIPTION OF EXAMPLE EMBODIMENT(S)

The following example embodiments and their aspects are described and illustrated in conjunction with apparatuses, methods, and systems which are meant to be illustrative examples, not limiting in scope.

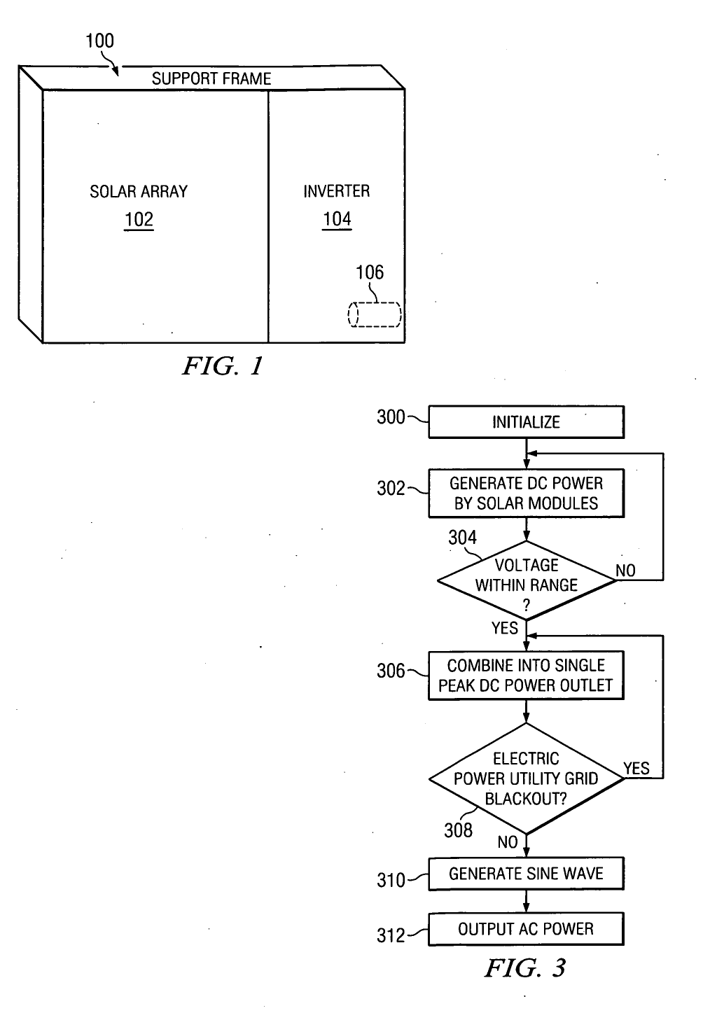

FIG. 1 illustrates a general overview of an integrated solar electric power generation system including a solar module 102, an inverter 104, a support frame 100, and a connector 106 according to one particular embodiment of the present invention. In the integrated solar electric power system, the solar module 102 is coupled with the inverter 104 and both the solar module 102 and the inverter 104 are mounted on a support frame 100. In some embodiments, support frame 100 may be made of aluminum, steel, wood or other types of materials that can provide the necessary structural support, thermal dissipation, and environmental protection. As will be described herein, a connector 106 is configured according to the present invention to supply electrical power generated by the integrated solar electric power system to a wall outlet; an extension cord may be used to connect the connector and a wall outlet.

As FIG. 1 illustrates, particular embodiments may operate on rooftops of a building, in a backyard or front yard, or on a balcony. For example, support frame 100 could be mounted on rooftops of a house, a commercial building, or any other building structure. Support frame 100 may also be mounted on the outside wall of a building structure or on the ground of a backyard of a building. In some embodiments, support frame 100 may be mounted on the balconies of an apartment in an apartment building. In other embodiments, support frame 100 may be mounted indoors. Connector 106 may be used to connect to an outside or inside wall outlet to supply the electric power generated by the integrated solar electric power generation system. In some embodiments, a power cable made of copper or other material may be used to safely carry the power generated by the solar electric system to an AC outlet socket. For example, a regular three prong household extension cord may be used to connect the integrated solar electric system to a wall outlet to supply power. There is no need to modify any existing electrical service panels. The generated electric power is made compatible with existing electrical utility grid by the integrated solar electric power system.

Depending on the method of deployment, in some embodiments, a stand, a mounting bracket, or other mechanisms for securing the system may be needed. In other embodiments, the integrated solar electric power system may be mounted on a system that tracks the movement of the Sun to maximize sunlight exposure and increase the amount of power that can be generated.

In some embodiment, the integrated solar electric power generation system may be used as a household backup generator. Just like any household backup generator, once plugged into an existing electric socket, the entire house will have electricity provided by the system in parallel with the utility supply. In other embodiments, excess power may be sent back through the same circuitry that electrical power is sent to the house. Through the Sine Wave Generator included in the inverter of the integrated solar electric power system, as described below, the inverter produces an AC output signal with a leading power phase angle in reference to the utility which in essence is a higher voltage than the utility in the time domain. As a result, excess power can be sent back to the utility power line with standard household utility meter.

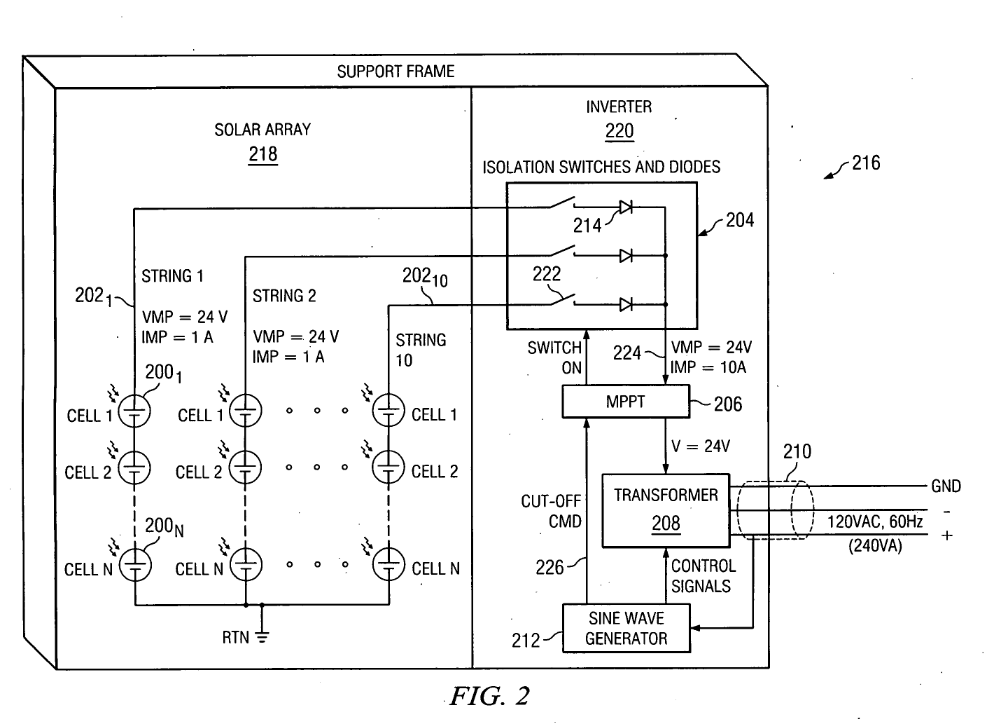

FIG. 2 illustrates, for didactic purposes, an integrated solar electric power generation system 206, which system may be used by an embodiment of the present invention. In FIG. 2, a 240-watt integrated solar electric power generation system 206 is illustrated. The symbols, abbreviations, and acronyms used in FIG. 2 include the following: Vmp stands for Voltage at maximum power, Imp stands for Current (I) at maximum power, MPPT stands for Maximum Power Point Tracking, RTN stands for electrical return, GND stands for electrical ground, V stands for Voltage, and A stands for Ampere.

Solar array 218 comprises power generation components, i.e., solar cells, which are typically grouped into modules, referred to as solar modules. Solar cells 200₁ to 200_{N} and solar modules are interconnected by current conducting wires. In some embodiments, the wires are made of copper or aluminum, and the collectively generated DC power is sent to inverter 220 to be converted to AC power.

In this particular embodiment, 10 strings of solar cells 202₁ to 202₁₀ are connected in parallel to produce a collective 24 V, 10 A power output, which is equivalent to 240 watts. Each string comprises N solar cells 200₁ to 200_{N} connected in series to produce 24 volts. The number N is determined by the selection of specific solar cells. For example, if the output of each solar cell has a voltage level of 2.4 volts, then 10 solar cells will be needed for a 24-volt output. The output of each string goes into inverter 220 where they are combined, but isolated from one another to achieve better reliability. As a result, the loss of one cell or string would not cause the loss or significant reduction of power output of solar array 218.

Among other functions it performs, inverter 220 converts the received DC power to AC power that is compatible with the power input requirements of household appliances and power loads. The inverter design needs to comply with applicable regulatory codes. For example, there is the UL Standard 1703 on Inverters, Converters, and Controllers for Independent Power System. To be able to sell excess power generated back to the utility company, the output of inverter 220 needs to be conditioned so that it is also compatible with the electrical grid requirement. For example, in the U.S., the output of the inverter must conform to the IEEE Standard 929-2000, Recommended Practice for Utility Interface of Photovoltaic (PV) system.

Inverter 220 comprises four primary functional units: DC power input isolation and on-off control unit 204, Maximum Power Point Tracking unit 206, DC-to-AC power transformation unit 208, and Sine Wave Generator unit 210.

In one embodiment, DC input Power Isolation and on-off control unit 204 comprises 10 inputs which come from the 10 strings of solar cells 202₁ to 202₁₀. Each string 202ᵢ (1≦i≦10) is isolated from others by series diodes 214. This function also contains built-in electronic FET (Field Effect Transistor) switches 222 that are either closed to allow the passage of power or opened to deny the passage of power, depending on the status of the solar cells. In some embodiments, the input voltage from each string of solar cells ranges from 12-volt to 24.5-volt. Switch 222 is in the closed position when the voltage from the associated solar string is within this range. To protect the system from over-voltage or under-voltage, switch 222 is in the opened position when the input voltage from its associated solar cell string 202ᵢ (1≦i≦10) is outside the 12-volt to 24.5-volt range.

Maximum Power Point Tracker (MPPT) unit 206 performs the summation of peak voltage and peak current from all strings 202ᵢ (1≦i≦10) into a single peak DC power output 224 with the voltage fixed at 24 volt. The DC power output 224 is sent to transformer 208. When the voltage from any string of solar array goes below 12 volts or above 24.5 volts, MPPT 206 sends a signal to the associated switch 222 to disconnect that solar cell string. MPPT 206 also stops sending the DC power output to the transformer during utility blackout and upon receiving a cut-off command 226 from Sine Wave Generator 212.

Transformer 208 is connected to the MPPT output by one or more electrical wires. The MPPT output is regulated at 24 volt DC. Transformer 208 comprises a connector 210 with three electrodes, wherein one of the electrodes is an electrical ground. The other two electrodes of connector 210 comprises a positive (“+”) electrode and a negative (“−”) electrode. In some embodiments, transformer 208 may comprise a filter to smooth out the AC voltage. In other embodiments, a common household three prong extension cord may be used to connect connector 210 to a wall outlet. One of the inlets of the three prong extension cord may be connected to connector 210 and the three prong plug of the extension cord may be plugged into the wall outlet to supply the AC electrical power generated by the integrated solar electric power generation system.

Sine Wave Generator 212 sends switching signals to the power switches of the primary winding of transformer 208 to create AC power output. In some embodiments, a microprocessor or controller inside Sine Wave Generator 212 stores the sine wave algorithm that enables the output of the inverter to track the grid voltage and to minimize output ripples on the power line. To meet the IEEE 929-2000 requirement for grid-tie inverters, the AC output voltage is sensed and rectified back to Sine Wave Generator 212 in order to track, copy, and regulate the AC power output from the transformer 208. When utility blackout condition is sensed, Sine Wave Generator 212 sends a command 226 to MPPT 206 to stop sending DC power output to transformer 208.

FIG. 3 illustrates an example process used for generating AC electric power by an integrated solar electric power generation system, which process may be used by an embodiment of the present invention. In the first step 300, the process initializes. In some embodiments, an integrated solar electric power system initializes when there is sufficient solar light energy for one or more solar cells to generate electric power. In step 302, the solar cells in the solar modules generate DC power. The process checks in step 304 whether the voltage of the DC power is within a range. In some embodiments, the input voltage from the one or more solar cells ranges from 12-volt to 24.5-volt. To protect the system from over-voltage or under-voltage, a switch may be used to cut off voltage power from a particular solar cell string when the input voltage from that particular solar cell string is outside the 12-volt to 24.5-volt range.

If the voltages from the solar cells are within the voltage range, the process in step 306 combines the peak voltage and peak current from all solar cells into a single peak DC power output with the voltage fixed at 24 volt DC. The process then checks whether there is any electric power utility grid blackout in step 308. If there is a blackout, the process goes back to step 306. If there is no blackout, the process in step 308 generates sine waves to create AC power. In some embodiments, a microprocessor or controller stores the sine wave algorithm that enables the output of an inverter to track the grid voltage and to minimize output ripples on the power line. In step 312, the process outputs the generated AC power through a connector. In some embodiments, a three prong connector comprising three electrodes is used wherein one of the electrodes is an electrical ground. An extension cord may be used to connect the connector to a wall outlet to supply the generated AC power. In some embodiments, the wall outlet may be located indoors, while in other embodiments, the wall outlet may be located outdoors.

The present invention has been explained with reference to specific embodiments. For example, while embodiments of the present invention have been described with reference to specific material, hardware and/or software components, those skilled in the art will appreciate that different combinations of material, hardware and/or software components may also be used. Other embodiments will be evident to those of ordinary skill in the art. It is therefore not intended that the present invention be limited, except as indicated by the appended claims.

What is claimed is:

1. A method comprising
providing an integrated solar array comprising
one or more solar modules wherein each solar module is operative to convert solar light energy into DC electric power;
one or more inverters wherein each inverter is operative to receive and convert the DC electric power to AC electric power;
providing a connector for the integrated solar array wherein an extension cord may be used to connect the connector and a wall outlet to supply the AC electric power.

2. The method of claim 1, wherein each solar module comprises one or more solar cells operative to generate DC electric power and one or more electrical wires connected to the one or more inverters.

3. The method of claim 1, wherein each inverter comprises a DC electrical power isolation unit, a maximum power point tracker, a transformer, and a sine wave generator.

4. The method of claim 1, wherein the connector comprises three electrodes wherein one of the electrodes provides electrical ground.

5. The method of claim 1, wherein the extension cord comprises a household electrical extension cord with a three prong plug.

6. The method of claim 1, wherein the wall outlet is located inside or outside a building structure.

7. The method of claim 1, wherein the AC electric power is used to provide power to household power loads through the wall outlet.

8. An integrated solar array system comprising
one or more solar modules wherein each solar module is operative to convert solar light energy into DC electric power;
an inverter connected to the solar modules by one or more electrical wires wherein each inverter is operative to receive and convert the DC electric power to AC electric power;
a connector connected to the inverter by one or more electrical wires wherein an extension cord may be used to connect the connector and a wall outlet to supply the AC electric power;
a frame, on which the solar modules, the inverter, and the connector are mounted.

9. The integrated solar array system of claim 8, wherein each inverter comprises
a DC electric power isolation unit comprising circuitry for controlling passage of power from the solar modules;
a maximum power point tracker comprising circuitry to combine generated DC electric power from the one or more solar modules;
a transformer comprising circuitry to transform the combined DC electric power;
a sine wave generator comprising a microprocessor to generate AC power output from the transformed DC electric power.

10. The integrated solar array system of claim 8, wherein connector comprises three electrodes wherein one of the electrodes provides electrical ground.
